(19) United States
(12) Patent Application Publication
(10) Pub. No.: US 2010/0006910 A1
(43) Pub. Date: Jan. 14, 2010

(54) IMAGE SENSOR

(75) Inventors: Kuniyuki Tani, Takatsuki-shi (JP); Yugo Nose, Anpachi-gun (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi (JP)

(21) Appl. No.: 12/500,443

(22) Filed: Jul. 9, 2009

(30) Foreign Application Priority Data
Jul. 10, 2008 (JP) 2008-180265

(51) Int. Cl. H01L 31/0216; H01L 31/112

(52) U.S. Cl. 257/292; 257/435; 257/E31.122; 257/E31.073

(57) ABSTRACT

An image sensor includes a photoelectric conversion portion generating signal charges, a voltage conversion portion for converting the signal charges to a voltage, a charge increasing portion for increasing the number of the signal charges stored in the photoelectric conversion portion, a first light shielding film formed to cover at least one part of the charge increasing portion and a second light shielding film provided separately from the first light shielding film and formed to cover the voltage conversion portion.

### CROSS-REFERENCE TO RELATED APPLICATIONS

The priority application number JP2008-180265, Image Sensor, Jul. 10, 2008, Kuniyuki Tani, Yugo Nose, upon which this patent application is based is hereby incorporated by reference.

### BACKGROUND OF THE INVENTION

1. Field of the Invention

The present invention relates to an image sensor, and more particularly, it relates to an image sensor comprising a region for increasing the number of signal charges.

2. Description of the Background Art

An image sensor (CMOS image sensor) comprising a region for multiplying (increasing) the number of electrons (signal charges) is known in general.

An image sensor (CMOS image sensor) comprising a photodiode portion for storing electrons generated by photoelectric conversion, having a photoelectric conversion function and a multiplier gate electrode applying an electric field for multiplying (increasing) the number of electrons by impact ionization is disclosed in general.

### SUMMARY OF THE INVENTION

An image sensor according to an aspect of the present invention comprises a photoelectric conversion portion generating signal charge, a voltage conversion portion for converting the signal charges to a voltage, a charge increasing portion for increasing the number of the signal charges stored in the photoelectric conversion portion, a first light shielding film formed to cover at least one part of the charge increasing portion and a second light shielding film provided separately from the first light shielding film and formed to cover the voltage conversion portion.

According to the aforementioned structure, the sensitivity of the image sensor can be further improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an overall structure of a CMOS image sensor according to a first embodiment of the present invention;

FIG. 2 is a plan view of a pixel according to the first embodiment of the present invention;

FIG. 3 is a plan view of a light shielding portion according to the first embodiment of the present invention;

FIG. 4 is a sectional view taken along the line 200-200 in FIG. 2;

FIG. 5 is a sectional view taken along the line 210-210 in FIG. 2;

FIG. 6 is a diagram showing the relation between the light shielding portion and incident light according to the first embodiment of the present invention;

FIG. 7 is a circuit diagram showing a circuit structure of the CMOS image sensor according to the first embodiment of the present invention;

FIG. 8 is a potential diagram for illustrating an electron transferring operation of the CMOS image sensor according to the first embodiment of the present invention;

FIG. 9 is a potential diagram for illustrating an electron multiplying operation of the CMOS image sensor according to the first embodiment of the present invention;

FIG. 10 is a plan view of a pixel according to a second embodiment of the present invention; and

FIG. 11 is a plan view of the pixel according to the second embodiment of the present invention.

### DESCRIPTION OF THE PREFERRED EMBODIMENTS

Embodiments of the present invention will be hereinafter described with reference to the drawings.

### First Embodiment

The first embodiment of the present invention is applied to an active CMOS image sensor employed as an exemplary image sensor.

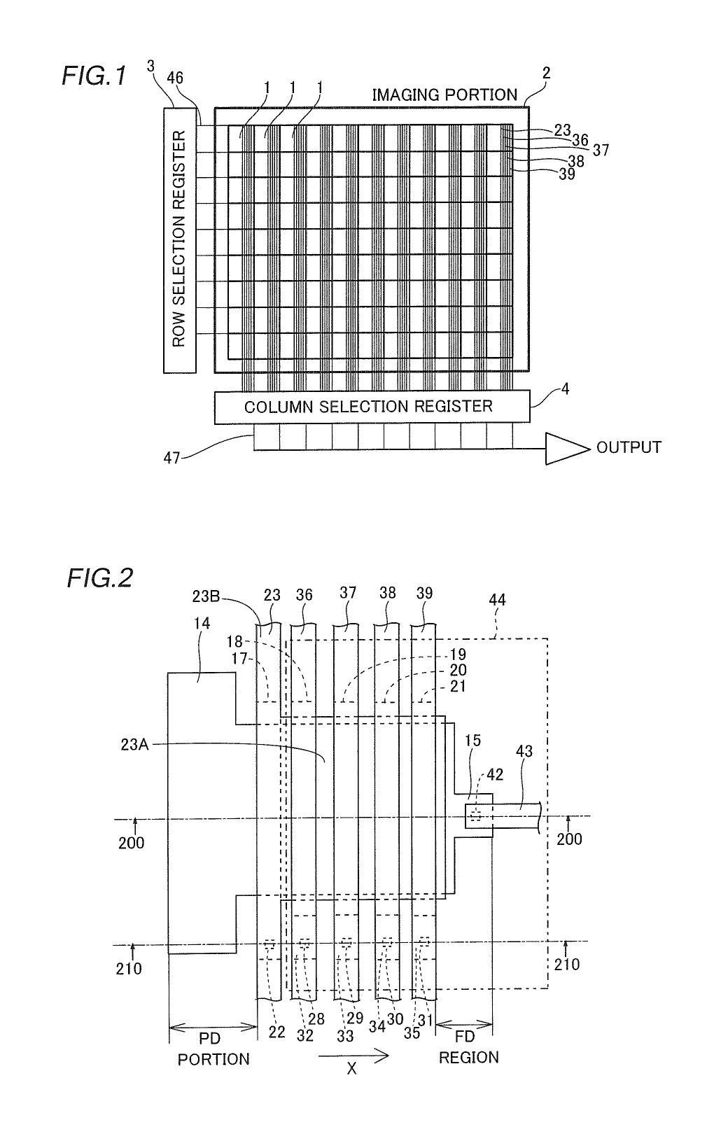

The CMOS image sensor according to the first embodiment comprises an imaging portion 2 including a plurality of pixels 1 arranged in the form of a matrix, a row selection register 3 and a column selection register 4, as shown in FIG. 1.

In pixels 1, element isolation regions 12 for isolating the pixels 1 from each other are formed on a surface of a p-type well region 11 formed on a surface of an n-type silicon substrate (not shown), as shown in FIG. 4. On the surface of the p-type well region 11 provided with each pixel 1 enclosed with the corresponding element isolation region 12, a photodiode (PD) portion 14 and a floating diffusion (FD) region 15 consisting of an n-type impurity region are formed at a prescribed interval to hold the buried layer 13 consisting of an n⁻-type impurity region therebetween. The buried layer 13 is an example of the “impurity region” in the present invention.

The PD portion 14 has a function of generating electrons in response to the quantity of incident light and storing the generated electrons. The PD portion 14 is formed to be adjacent to the corresponding element isolation region 12 as well as to the buried layer 13. The FD region 15 has a function of holding signal charges formed by transferred electrons and converting the signal charges to a voltage. The FD region 15 is formed to be adjacent to the buried layer 13.

A gate insulating film 16 made of SiO₂ is formed on an upper surface of the buried layer 13. On the gate insulating film 16, a transfer gate electrode 17 made of a polysilicon film, a multiplier gate electrode 18, a transfer gate electrode 19, a storage gate electrode 20 and a read gate electrode 21 are formed in this order from a side of the PD portion 14 toward a side of the FD region 15. An electron multiplying portion 13A is provided on a portion of the buried layer 13 located under the multiplier gate electrode 18 and an electron storage portion 13B is provided on a portion of the buried layer 13 located under the storage gate electrode 20. The electron multiplying portion 13A is an example of the “charge increasing portion” in the present invention. The transfer gate electrode 17, the multiplier gate electrode 18, the transfer gate electrode 19, the storage gate electrode 20 and the read gate electrode 21 are examples of the “first gate electrode”, the “second gate electrode”, the “third gate electrode”, the “fourth gate electrode” and the “fifth gate electrode” in the present invention, respectively.

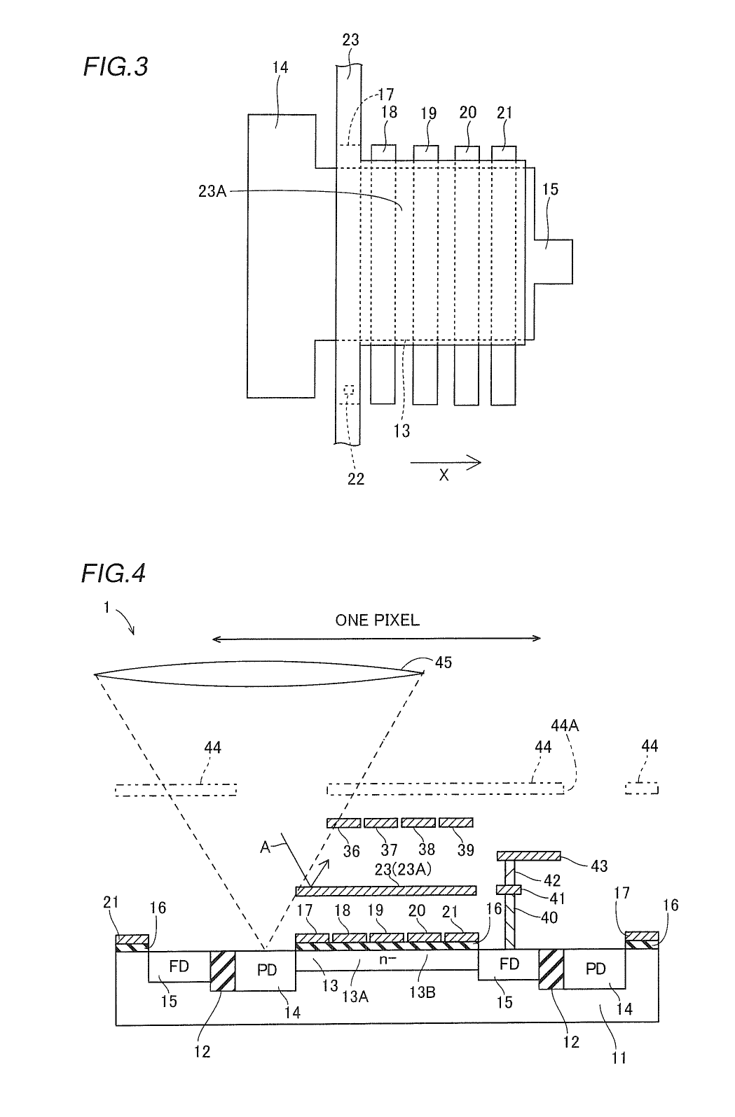

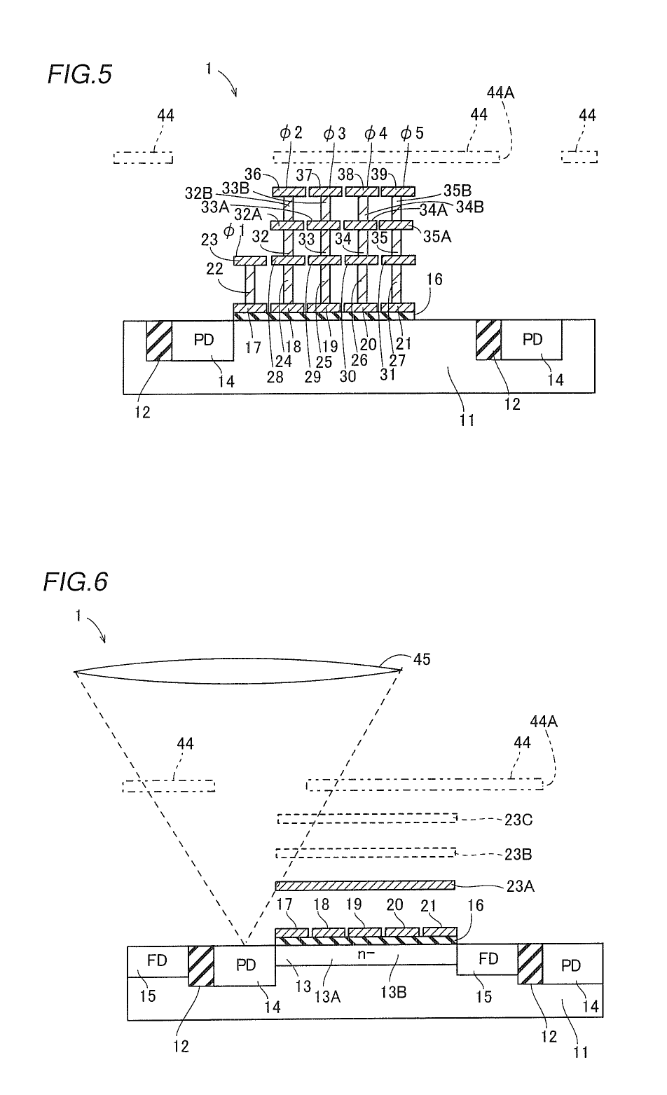

As shown in FIG. 5, a signal line 23 supplying a clock signal φ1 for voltage control is electrically connected to the transfer gate electrode 17 through a contact portion 22. The signal line 23 has a signal line portion 23B extending in a direction intersecting with an electron transfer direction (along arrow X), as shown in FIG. 3. The signal line 23 is arranged to be adjacent to the PD portion 14 in plan view, and has a light shielding portion 23A formed to protrude to the side of the FD region 15 (along arrow X). This light shielding portion 23A is formed to cover upper portions of the multiplier gate electrode 18, the transfer gate electrode 19, the storage gate electrode 20 and the read gate electrode 21. In other words, the light shielding portion 23A is provided to cover a substantially overall surface of the buried layer 13. Thus, even when partial light (arrow A shown in FIG. 4) incident through a microlense 45 described later is incident not upon the PD portion 14 but on the side of the multiplier gate electrode 18, the partial incident light is blocked by the light shielding portion 23A. An end of the signal line 23 on the side of the PD portion 14 is located closer to the PD portion 14 than an end of a signal line 36, described later, on the side of the PD portion 14. The signal line 23 is an example of the “first signal line” in the present invention. The light shielding portion 23A is an example of the “first light shielding film” or the “light shielding film portion” in the present invention. As shown in FIG. 4, the signal line 23 (light shielding portion 23A) is formed by a wiring layer located on a lower layer than a wiring layer (wire of the third layer) formed with signal lines 36 to 39 described layer. Thus, the light shielding portion 23A does not block light incident through the microlense 45 unlikely to light shielding portions 23B (wire of the second layer) and 23C (wire of the third layer) shown by a dotted line in FIG. 6.

As shown in FIG. 5, the signal lines 36 to 39 supplying clock signals φ2, φ3, φ4 and φ5 for voltage control are electrically connected to the multiplier gate electrode 18, the transfer gate electrode 19, the storage gate electrode 20 and the read gate electrode 21 through contact portions 24 to 27, pad layers 28 to 31, contact portions 32 to 35, pad layers 32A to 35A and contact portions 32B to 35B respectively. The signal lines 23 and 36 to 39 are formed every row of the pixels 1 arranged in the form of a matrix and connected to the column selection register 4, as shown in FIG. 1. The signal lines 36, 37, 38 and 39 are examples of the “second signal line”, the “third signal line”, the “fourth signal line” and the “fifth signal line” in the present invention respectively.

As shown in FIG. 4, a wire 43 (wire of the second layer) for extracting a signal is electrically connected to the FD region 15 through a contact portion 40, a pad layer 41 (wire of the first layer) and a contact portion 42. The wire 43 is an example of the “voltage conversion wire” in the present invention.

A wiring layer 44 consisting of a wire of the fourth layer, supplying power supply voltage (VDD) is formed above the signal lines 36 to 39. The wiring layer 44 is provided with an opening 44A on a region corresponding to the PD portion 14 and the signal line 23 on the transfer gate electrode 17, and has a function as a light shielding film covering a region other than the region corresponding to the PD portion 14 and the signal line 23 on the transfer gate electrode 17. In other words, the end of the signal line 23 on the side of the PD portion 14 protrudes from the opening 44A in plan view. The wiring layer 44 is an example of the “second light shielding film” or the “power supply voltage wire” in the present invention. The microlense 45 is provided to be opposed to the opening 44A above the region corresponding to the opening 44A of the wiring layer 44. The microlense 45 has a function of condensing light incident on the pixel 1. The opening 44A of the wiring layer 44 may be formed by hollowing the wiring layer 44 to have the same shape as the shape of the PD portion 14 in plan view. The microlense 45 is an example of the “lens” in the present invention.

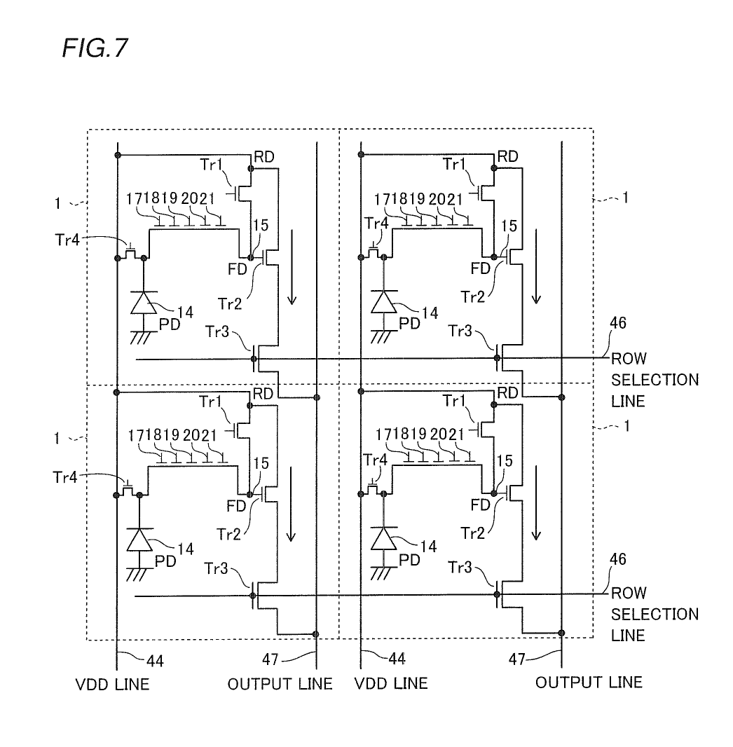

As shown in FIG. 7, each of the pixels 1 is provided with a reset gate transistor Tr1, an amplification transistor Tr2, a pixel selection transistor Tr3 and a global reset transistor Tr4. A gate of the reset gate transistor Tr1 is connected to a reset gate line (not shown) and supplied with a reset signal. The reset gate transistor Tr1 has a first source/drain connected to the wiring layer 44 (VDD line). The reset gate transistor Tr1 has a second source/drain connected to the FD region 15. The amplification transistor Tr2 has a first source/drain connected to a first source/drain (reset drain RD) of the reset gate transistor Tr1 and a second source/drain connected to a first source/drain of the pixel selection transistor Tr3. The pixel selection transistor Tr3 has a gate connected to a row selection line 46 and a second source/drain connected to an output line 47. The global reset transistor Tr4 has a first source/drain connected to the PD portion 14 and a second source/drain connected to the wiring layer 44. The row selection line 46 and the output line 47 are connected to the row selection register 3 and the column selection register 4 respectively, as shown in FIG. 1.

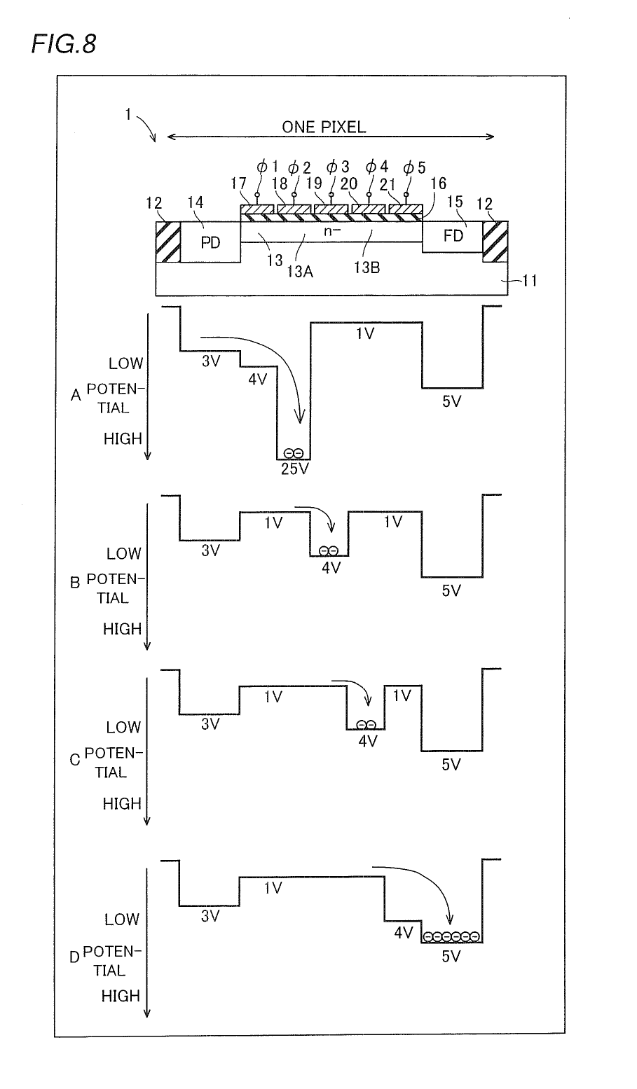

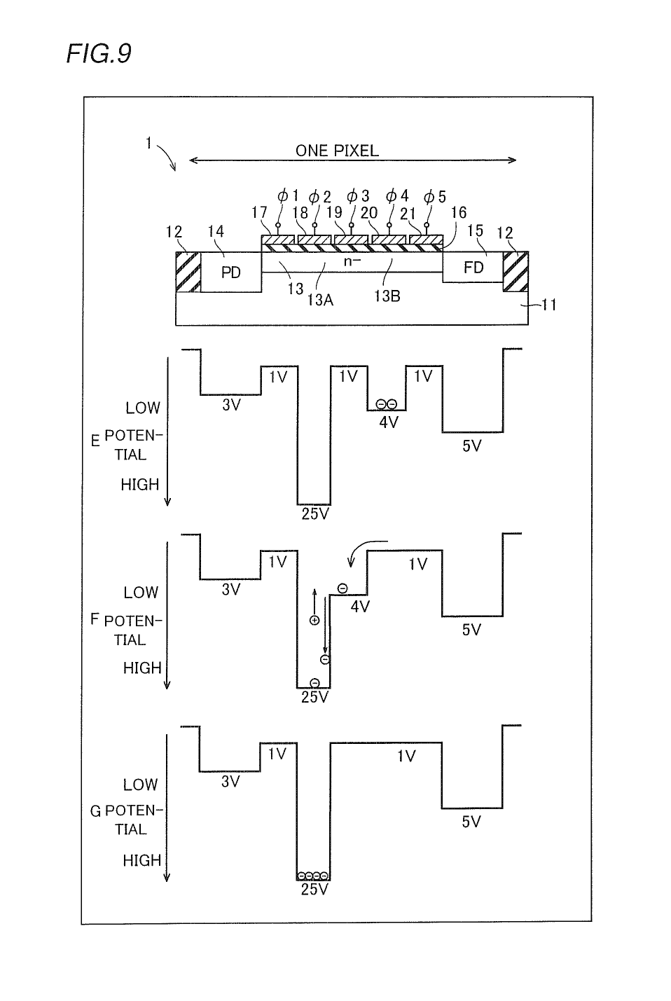

Electron transferring and multiplying operations of the CMOS image sensor according to the first embodiment of the present invention will be described with reference to FIGS. 8 and 9.

When light is incident upon the PD portion 14, electrons are generated in PD portion 14 by photoelectric conversion. In a period A shown in FIG. 8, electrons generated by the PD portion 14 (about 3 V) are transferred to a portion (electron multiplying portion 13A) of the buried layer 13 located under the multiplier gate electrode 18 (higher potential of about 25 V) through a portion of the buried layer 13 located under the transfer gate electrode 17 (about 4V). Thereafter the electrons are transferred to a portion of the buried layer 13 located under the transfer gate electrode 19 in a period B and transferred to a portion (electron storage portion 13B) of the buried layer 13 located under the storage gate electrode 20 in a period C. In a period D, the multiplied electrons, described later, are transferred to the FD region 15 (about 5 V).

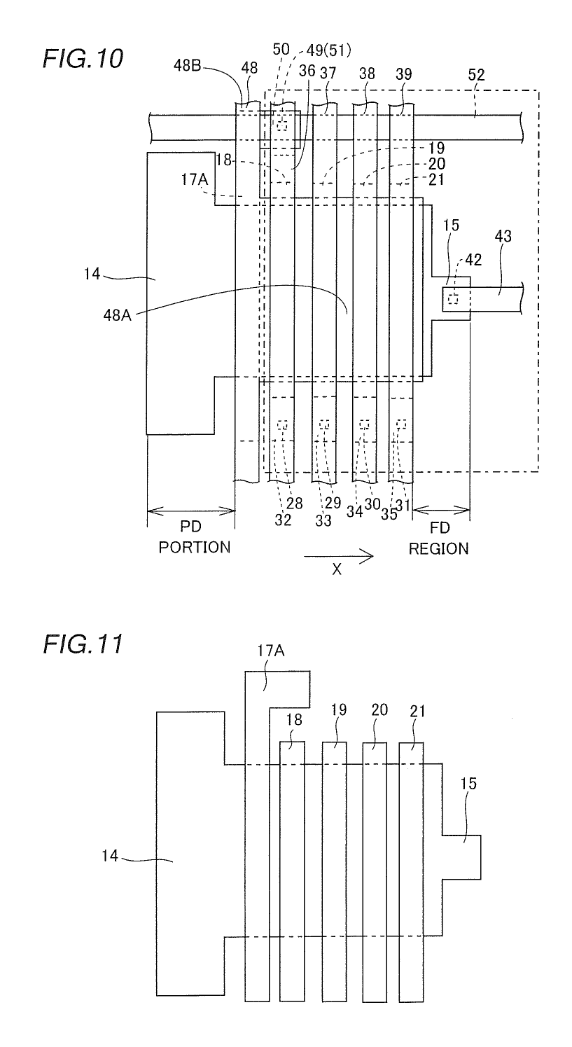

In the electron multiplying operation, the multiplier gate electrode 18 is brought into an ON-state in a period E shown in FIGS. 10 and 9, and the transfer gate electrode 19 is brought into an ON-state in a period F, in a state where the electrons are stored in the portion (electron storage portion 13B) of the buried layer 13 located under the storage gate electrode 20 by performing the operations in the periods A to C in FIG. 8. Then the storage gate electrode 20 is brought into an OFF-state, so that the electrons stored in the electron storage portion 13B are transferred to the portion (electron multiplying portion 13A), which has a higher potential, of the buried layer 13 located under the multiplier gate electrode 18 through the portion of the buried layer 13 located under the transfer gate electrode 19 (about 4 V) and are multiplied by impact ionization. In a period G, the transfer gate electrode 19 is brought into an OFF-state, thereby completing the multiplying operation. The aforementioned operations in periods A to C and periods E to G are performed a plurality of times. After ending the electron multiplying operation, the electrons are stored in the portion (electron multiplying portion 13A) of the buried layer 13 located under the multiplier gate electrode 18 and are read to the FD region 15 every row. Thus, the global shutter performing reset of the electrons stored in all of the pixels and start of storage of the electrons simultaneously can be achieved.

According to the first embodiment, as hereinabove described, the CMOS image sensor according to the first embodiment comprises the light shielding portion 23A formed to cover the buried layer 13 (the electron multiplying portion 13A and the electron storage portion 13B), whereby light can be inhibited from being incident upon the buried layer 13 during the electron multiplying operation, and hence influence of light incident upon the buried layer 13 (noise caused by electrons newly generated by photoelectric conversion) can be suppressed even when the period of the electron multiplying operation is increased. Thus, it can take a long time to multiply electrons which are stored for a short imaging period, and hence the speed of a shutter can be increased while enhancing the sensitivity of the image sensor.

According to the first embodiment, as hereinabove described, the CMOS image sensor according to the first embodiment comprises the wiring layer 44 formed to cover the FD region 15, whereby light can be inhibited from being incident upon the FD region 15 until the electrons stored in the FD region 15 are read as a signal, and hence occurrence of noise can be suppressed.

According to the first embodiment, as hereinabove described, the light shielding portion 23A is formed by the wiring layer located on a lower layer than the wiring layer forming the wiring layer 44, whereby light incident from the microlense 45 can be inhibited from being partially blocked unlikely to the light shielding portions 23B and 23C (see FIG. 6) formed on the wiring layers of the upper layer, for example. The charge/voltage conversion factor of the FD region 15 is substantially proportional to a value obtained by dividing 1 by capacitance of the FD region 15 (1/capacitance of the FD region 15). In other words, the capacitance of the FD region 15 is desirably small for obtaining (improving sensitivity) a read voltage having a large voltage width at a small number of charges (electrons). According to the first embodiment, as hereinabove described, the wiring layer 44 (light shielding film blocking light incident upon the FD region 15) is formed by the wiring layer located on an upper layer than the wiring layer forming the wire 43, whereby capacitance between the FD region 15 and the wiring layer 44 is reduced dissimilarly to a case of forming the wiring layer 44 by the wiring layer of the lower layer, and hence a read voltage having a large voltage width can be obtained (sensitivity can be improved) at a small number of charges (electrons).

According to the first embodiment, as hereinabove described, the light shielding portion 23A is formed by the signal line 23, whereby this can be used both as the signal line 23 and the light shielding portion 23A dissimilarly to a case where a wire forming the light shielding portion 23A and a signal line for applying a voltage to the transfer gate electrode 17 are separately provided, and hence the structure of the CMOS image sensor can be simplified.

According to the first embodiment, as hereinabove described, the light shielding portion 23A is formed by the signal line 23 provided to be adjacent to the PD portion 14 in plan view, whereby the signal line 23 applies an ON-state signal only once in the electron transferring and multiplying operations in order to transfer electrons from the PD portion 14 to the electron multiplying portion 13A, and hence a parasitic capacitance between the light shielding portion 23A and the multiplier gate electrode 18 located under the light shielding portion 23A can be inhibited from change dissimilarly to a case of a signal line repeating an ON-state and an OFF-state a plurality of times such as other signal lines 36 to 39.

According to the first embodiment, as hereinabove described, the signal lines 36 to 39 other than the signal line 23 in the signal lines 23 and 36 to 39 are formed to be covered by the wiring layer 44, whereby size of the opening 44A of the wiring layer 44 can be increased dissimilarly to a case where the wiring layer 44 covers all of the signal lines 23 and 36 to 39, and hence the quantity of light incident upon the PD portion 14 can be increased.

According to the first embodiment, as hereinabove described, the light shielding portion 23A is formed to cover the substantially overall surface of the buried layer 13 in plan view, whereby the light shielding portion 23A can easily inhibit light from being incident upon the buried layer 13.

According to the first embodiment, as hereinabove described, the signal line 23 includes the signal line portion 23B extending in the direction intersecting with the electron transfer direction and the light shielding portion 23A protruding to the side of the FD region 15 from the signal line portion 23B, whereby the signal line portion 23B and the light shielding portion 23A can be easily integrally formed with each other.

According to the first embodiment, as hereinabove described, the wiring layer 44 supplying power supply voltage has the opening 44A on the region corresponding to the PD portion 14 in plan view, whereby light can be easily incident upon the PD portion 14.

According to the first embodiment, as hereinabove described, the microlense 45 is arranged to be opposed to the opening 44A provided in the wiring layer 44, whereby light incident upon the microlense 45 can be incident upon the PD portion 14 through the opening 44A.

### Second Embodiment

In a CMOS image sensor according to a second embodiment, a light shielding portion 48A is formed by a wire 48 supplying a ground potential (GND), dissimilarly to the aforementioned first embodiment.

In the CMOS image sensor according to the second embodiment, the wire 48 supplying a ground potential (GND) has a ground wiring portion 48B extending in a direction intersecting with an electron transfer direction (along arrow X), as shown in FIG. 10. The wire 48 has the light shielding portion 48A formed to protrude to a side of the FD region 15 (along arrow X) in plan view. This light shielding portion 48A is formed to cover upper portions of a multiplier gate electrode 18, a transfer gate electrode 19, a storage gate electrode 20 and a read gate electrode 21, similarly to the light shielding portion 23A (see FIGS. 2 and 4) of the aforementioned first embodiment. The wire 48 is an example of the “ground wire” in the present invention. The light shielding portion 48A is an example of the “first light shielding film” or the “light shielding film portion” in the present invention. A transfer gate electrode 17A is formed in an L-shape (see FIG. 11) dissimilarly to the aforementioned first embodiment, and is electrically connected to a signal line 52 through a contact portion 49, a pad layer 50 and a contact portion 51. The signal line 52 is formed to transmit a signal identical with the signal of the signal line 23 according to the aforementioned first embodiment. The remaining structure of the second embodiment is similar to that of the aforementioned first embodiment. The operation of the second embodiment is similar to that of the aforementioned first embodiment.

According to the second embodiment, as hereinabove described, the wire 48 includes the ground wiring portion 48B extending in the direction intersecting with the electron transfer direction and the light shielding portion 48A protruding from the ground wiring portion 48B to the side of the FD region 15, whereby the ground wiring portion 48B and the light shielding portion 48A can be integrally formed with each other.

The remaining effects of the second embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while each of the aforementioned first and second embodiments is applied to the active CMOS image sensor amplifying signal charges in each pixel 1 as an exemplary image sensor, the present invention is not restricted to this but is also applicable to a passive CMOS image sensor not amplifying signal charges in each pixel 1.

While five of the transfer gate electrode 17, the multiplier gate electrode 18, the transfer gate electrode 19, the storage gate electrode 20 and the read gate electrode 21 are provided between the PD portion 14 and the FD region 15 in each of the aforementioned first and second embodiments, the present invention is not restricted to this but three or four electrodes may be formed between the PD portion 14 and the FD region 15.

While the buried layer 13, the PD portion 14 and the FD region 15 are formed on the surface of the p-type well region 11 formed on the surface of the n-type silicon substrate (not shown) in each of the aforementioned first and second embodiments, the present invention is not restricted to this but the buried layer 13, the PD portion 14 and the FD region 15 may be formed on the surface of the p-type silicon substrate.

While electrons are employed as signal charges in each of the aforementioned first and second embodiments, the present invention is not restricted to this but holes may alternatively be employed as signal charges by entirely reversing the conductivity type of the substrate impurity and the polarities of the applied voltages.

While the light shielding portion 23A (48A) is formed to cover the upper portions of the transfer gate electrode 17, the multiplier gate electrode 18, the transfer gate electrode 19, the storage gate electrode 20 and the read gate electrode 21 in each of the aforementioned first and second embodiments, the present invention is not restricted to this but the light shielding portion 23A (48A) may cover only the upper portions of the electrodes involved in the electron multiplying operation in the transfer gate electrode 17, the multiplier gate electrode 18, the transfer gate electrode 19, the storage gate electrode 20 and the read gate electrode 21.

While the light shielding portion 23A is formed by the signal line 23 adjacent to the PD portion 14 in plan view in the aforementioned first embodiment, the present invention is not restricted to this but the light shielding portion 23A may be formed by the signal lines other than the signal line 23.

What is claimed is:

1. An image sensor comprising:
a photoelectric conversion portion generating signal charges;
a voltage conversion portion for converting the signal charges to a voltage;
a charge increasing portion for increasing the number of the signal charges stored in said photoelectric conversion portion;
a first light shielding film formed to cover at least one part of said charge increasing portion; and
a second light shielding film provided separately from said first light shielding film and formed to cover said voltage conversion portion.

2. The image sensor according to claim 1, wherein
said first light shielding film is formed on a lower layer than said second light shielding film.

3. The image sensor according to claim 1, further comprising a plurality of signal lines provided between said photoelectric conversion portion and said voltage conversion portion in plan view, wherein
a first signal line which is one of said plurality of signal lines is formed on a lower layer than the signal lines other than said first signal line, and
said first light shielding film is constituted by said first signal line.

4. The image sensor according to claim 3, wherein
said first signal line is arranged to be adjacent to said photoelectric conversion portion in plan view.

5. The image sensor according to claim 4, wherein
said second light shielding film is formed to cover the signal line other than said first signal line in said plurality of signal lines and at least one part of said first light shielding film in plan view.

6. The image sensor according to claim 1, further comprising a voltage conversion wire for supplying a voltage applied to said voltage conversion portion, wherein
said first light shielding film is provided on a lower layer than said voltage conversion wire, and said second light shielding film is provided on an upper layer than said voltage conversion wire.

7. The image sensor according to claim 1, further comprising a plurality of signal lines provided between said photoelectric conversion portion and said voltage conversion portion in plan view, wherein
said plurality of signal lines include a first signal line constituting said first light shielding film and a second signal line supplying a voltage applied to said charge increasing portion, and
an end of said first signal line on a side of said photoelectric conversion portion is located closer to said photoelectric conversion portion than an end of said second signal line on the side of said photoelectric conversion portion in plan view.

8. The image sensor according to claim 7, wherein
said first signal line supplies a voltage to a first gate electrode applying a voltage for transferring charges, and said second signal line supplies a voltage to a second gate electrode applying a voltage to said charge increasing portion, and
said plurality of signal lines include a third signal line supplying a voltage to a third gate electrode applying a voltage for transferring the charges, a fourth signal line supplying a voltage to a fourth gate electrode applying a voltage for storing the charges and a fifth signal line supplying a voltage to a fifth gate electrode applying a voltage for reading the charges, and said first gate electrode, said second gate electrode, said third gate electrode, said fourth gate electrode and said fifth gate electrode are arranged between said photoelectric conversion portion and said voltage conversion portion in plan view.

9. The image sensor according to claim 8, further comprising an impurity region provided between said photoelectric conversion portion and said voltage conversion portion, wherein
said first gate electrode, said second gate electrode, said third gate electrode, said fourth gate electrode and said fifth gate electrode are provided on a surface of said impurity region through a gate insulating film, and said charge increasing portion is provided on a portion of said impurity region located under said second gate electrode.

10. The image sensor according to claim 1, further comprising an impurity region provided between said photoelectric conversion portion and said voltage conversion portion, wherein
said first light shielding film is formed to cover a substantial overall surface of said impurity region in plan view.

11. The image sensor according to claim 1, further comprising a plurality of signal lines provided between said photoelectric conversion portion and said voltage conversion portion in plan view, wherein
a first signal line which is one of said plurality of signal lines is formed on a lower layer than the signal line other than said first signal line, and
said first light shielding film is constituted by said first signal line, and said first signal line includes a signal line portion extending in a direction intersecting with a signal charge transfer direction and a light shielding film portion protruding to a side of said voltage conversion portion from said signal line portion.

12. The image sensor according to claim 11, wherein
the signal line other than said first signal line in said plurality of signal lines is provided between said light shielding film portion of said first signal line and said second light shielding film.

13. The image sensor according to claim 12, wherein
said second light shielding film is formed by a power supply voltage wire supplying a power supply voltage.

14. The image sensor according to claim 13, wherein
said second light shielding film has an opening on a region corresponding to said photoelectric conversion portion in plan view.

15. The image sensor according to claim 14, wherein
an end of said first light shielding film on a side of said photoelectric conversion portion is formed to protrude from said opening in plan view.

16. The image sensor according to claim 14, further comprising a lens for condensing light, wherein
said lens is arranged to be opposed to said opening.

17. The image sensor according to claim 1, wherein
said first light shielding film is formed by a ground wire supplying a ground potential.

18. The image sensor according to claim 17, wherein
said ground wire is arranged to be adjacent to said photoelectric conversion portion in plan view.

19. The image sensor according to claim 17, wherein
said ground wire includes a ground wiring portion extending in a direction intersecting with a signal charge transfer direction, and a light shielding film portion protruding to a side of said voltage conversion portion from said ground wiring portion.

20. The image sensor according to claim 1, further comprising a plurality of pixels arranged in the form of a matrix, wherein
said photoelectric conversion portion, said voltage conversion portion, said charge increasing portion and said first light shielding film are provided every pixel.
